(19) United States
(12) Patent Application Publication
(10) Pub. No.: US 2021/0143148 A1
(43) Pub. Date: May 13, 2021

(54) SEMICONDUCTOR DEVICE

(71) Applicant: Fuji Electric Co., Ltd., Kanagawa (JP)

(72) Inventor: Akihiro JONISHI, Nagano (JP)

(73) Assignee: Fuji Electric Co., Ltd., Kanagawa (JP)

(21) Appl. No.: 17/061,441

(22) Filed: Oct. 1, 2020

(30) Foreign Application Priority Data
Nov. 13, 2019 (JP) 2019-205768

(51) Int. Cl. H01L 27/06; H01L 29/06; H01L 29/10; H01L 29/78; H03K 3/356; H03K 17/687

(52) U.S. Cl. CPC H01L 27/0629; H01L 29/063; H03K 17/6872; H01L 29/7802; H03K 3/356113; H01L 29/1095

(57) ABSTRACT

A semiconductor device includes an n type first semiconductor region in which a first parasitic diode is formed with a p type semiconductor substrate; an n type second semiconductor region in which a second parasitic diode is formed with the p type semiconductor substrate; a control circuit in the second semiconductor region outputting a gate control signal, a gate drive circuit in the second semiconductor region; a level shift circuit that converts the gate control signal to a converted gate control signal and outputs the converted gate control signal to the gate drive circuit; a diode connected to a path of a noise current caused by a negative voltage noise passing through the second parasitic diode, the diode being connected to the path in a direction opposite to a direction in which the noise current would flow; and a capacitor connected to an anode of said diode.

### BACKGROUND OF THE INVENTION

### Technical Field

The present invention relates to a semiconductor device such as a high voltage integrated circuit (HVIC).

### Background Art

Conventionally, in a power conversion device such as an industrial inverter, when driving a gate of a switching element such as an insulated gate bipolar transistor (IGBT) that constitutes a power conversion bridge circuit, an isolation transformer and a photocoupler are used for electrical insulation between a control circuit and a gate drive circuit. However, in recent years, a high voltage integrated circuit (HVIC) that does not employ the electric isolation is gaining popularity mainly for low capacity applications in order to reduce costs (see Patent Documents 1 to 4).

The HVIC generally operates with a low-voltage side control circuit that operates using the ground potential (GND potential) as a reference potential, a high-voltage side gate drive circuit that operates using a VS potential higher than the GND potential as a reference potential and using a VB potential higher than the VS potential as the power supply potential, and a level shift circuit arranged between the control circuit and the gate drive circuit. The level shift circuit converts an input signal from the control circuit that is generated with reference to the GND potential to a signal that uses the VS potential as the referenced signal, and outputs the converted signal to the gate drive circuit.

### RELATED ART DOCUMENT

### Patent Document

Patent Document 1: Japanese Patent No. 3214818
Patent Document 2: U.S. Pat. No. 6,211,706
Patent Document 3: U.S. Pat. No. 6,967,518
Patent Document 4: Japanese Patent No. 5987991

### SUMMARY OF THE INVENTION

When the load connected to the switching element driven by the HVIC is inductive, the VS potential impulsively drops below the GND potential due to the counter electromotive force generated in the load at the moment when the switching element is turned off, thereby causing the −VS noise (negative voltage noise) to occur. When the voltage (absolute value) of the −VS noise is greater than the voltage between the VB terminal and the VS terminal, not only the VS potential, but also the VB potential becomes lower than the GND potential.

In the HVIC using the self-isolation scheme described in Patent Document 1, when the VB potential becomes lower than the GND potential, the parasitic diode formed between the VB terminal and the GND terminal is forward biased. When the forward voltage of the parasitic diode becomes 0.6 V or more, the parasitic diode becomes conductive. Due to the conduction of the parasitic diode, a noise current flows from the p type semiconductor substrate connected to the GND terminal to the gate drive circuit connected to the VB terminal, causing malfunction of the gate drive circuit. This problem also exists in HVICs that use a junction isolation scheme.

Further, Patent Documents 2 and 3 describe a technique of applying a negative bias to the substrate potential using a negative voltage power supply. By this technique, it is possible to prevent the parasitic diode from being forward-biased when the −VS noise is generated at the VS terminal, and prevent malfunction of the gate drive circuit. However, since a negative voltage power supply is required, the cost increases.

Further, Patent Document 4 discloses an HVIC of a system (substrate/GND separation system) in which a diode separates a substrate potential and a GND potential. In this technique, when the −VS noise is generated at the VS terminal, the diode is reverse-biased and the parasitic diode is prevented from being forward-biased, and the malfunction of the gate drive circuit can be prevented. However, when the dV/dt noise is generated due to the fluctuation of the VS potential due to the switching operation of the switching element, the substrate potential may rise above the GND potential and an abnormal current may flow into the control circuit, causing a malfunction.

In view of the above problems, it is an object of the present invention to provide a semiconductor device capable of preventing a circuit malfunction due to the −VS noise and the dV/dt noise.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purposes of the present invention, as embodied and broadly described, in one aspect, the present disclosure provides a semiconductor device, comprising: a first semiconductor substrate of a first conductivity type; a first semiconductor region of a second conductive type, provided in the first semiconductor substrate, forming a first parasitic diode with the first semiconductor substrate; a second semiconductor region of the second conductive type, provided in the first semiconductor substrate so as to be separated from the first semiconductor region, forming a second parasitic diode with the first semiconductor substrate; a control circuit that is provided in the first semiconductor region and outputs a gate control signal; a gate drive circuit provided in the second semiconductor region; a level shift circuit that converts the gate control signal from the control circuit to a converted gate control signal, and outputs the converted gate control signal to the gate drive circuit; a diode connected to a path of a noise current caused by a negative voltage noise passing through the second parasitic diode, the diode being connected to the path in a direction opposite to a direction in which the noise current would flow; and a capacitor connected to an anode of said diode.

In another aspect, the present invention provides a semiconductor device, comprising: a first semiconductor substrate of a first conductivity type; a first semiconductor region of a second conductive type, provided in the first semiconductor substrate; a second semiconductor region of the second conductive type, provided in the first semiconductor substrate so as to be separated from the first semiconductor region; a third semiconductor region of the first conductivity type provided in the first semiconductor region; a fourth semiconductor region of the first conductivity type provided in the second semiconductor region; a control circuit that is provided in the first semiconductor region and outputs a first gate control signal having a potential of the third semiconductor region as a reference potential; a gate drive circuit that is provided in the second semiconductor region and operates using a potential of the fourth semiconductor region as a reference potential; a level shift circuit that converts the first gate control signal that has the potential of the third semiconductor region as the reference potential output from the control circuit to a second gate control signal that has the potential of the fourth semiconductor region as a reference potential, and outputs the second gate control signal to the gate drive circuit; a diode, a cathode of which is connected to the third semiconductor region and an anode of which is connected to the first semiconductor substrate; and a capacitor connected in parallel with the diode.

According to the present invention, it is possible to provide a semiconductor device capable of preventing a malfunction of a circuit due to the −VS noise and the dV/dt noise.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is an equivalent circuit schematic of a semiconductor device according to an embodiment of the present invention.

FIG. 2 is a plan view of the semiconductor device according to the embodiment of the present invention.

FIG. 3 is a cross-sectional view taken along the line A-A of FIG. 2.

FIG. 4 is a cross-sectional view taken along the line B-B of FIG. 2.

FIG. 5 is a plan view of a gate driver IC chip of the embodiment of the present invention.

FIG. 6 is a cross-sectional view taken along the line A-A of FIG. 5.

FIG. 7A is a plan view of a diode and capacity chip in the embodiment of the present invention.

FIG. 7B is a cross-sectional view taken along the line A-A of FIG. 7A.

FIG. 8 is a cross-sectional view of a high withstand voltage diode chip in the embodiment of the present invention.

FIG. 9 is a plan view of a gate driver IC chip according to a first comparison example.

FIG. 10 is a cross-sectional view taken along the line A-A of FIG. 9.

FIG. 11 is an equivalent circuit schematic of the semiconductor device of the first comparison example.

FIG. 12 is an equivalent circuit diagram of a semiconductor device according to a second comparison example.

FIG. 13A is a graph showing a time change of the VS potential when noises occurs

FIG. 13B is a graph showing a time change of the Psub potential when noises occur.

FIG. 14 is an equivalent circuit schematic of a semiconductor device according to a first modified example of the embodiment of the present invention.

FIG. 15 is an equivalent circuit schematic of a semiconductor device according to a second modified example of the embodiment of the present invention.

FIG. 16 is an equivalent circuit schematic of a semiconductor device according to a third modified example of the embodiment of the present invention.

### DETAILED DESCRIPTION OF EMBODIMENTS

Hereinafter, embodiments of the present invention will be described with reference to the drawings. In the description of the drawings, the same or similar parts are denoted by the same or similar reference numerals, and overlapping description will be omitted. Further, the drawings are schematic, and the relationship between the thickness and the plane dimensions, the thickness ratio among respective layers, and the like may differ from the actual ones. Further, there may be portions having different dimensional relationships and ratios among drawings. Further, the embodiments described below exemplify devices and methods for embodying the technical idea of the present invention and do not unduly limit the present invention to specific materials, shapes, structures, arrangements, and the like of the disclosed embodiments.

In addition, in the present specification, the definitions of directions such as up and down are provided merely for convenience of description, and do not limit the technical idea of the present invention. For example, it is needless to say that when the object is rotated by 90°, the upper and lower sides are converted into left and right, and when the object is rotated by 180°, the upper and lower sides are inverted.

In addition, in the present specification, the “first main electrode region” means a semiconductor region which is either a source region or a drain region in an insulated gate FET (MISFET) or an insulated gate static induction transistor (MISSIT). In the insulated gate bipolar transistor (IGBT), the “first main electrode region” means a semiconductor region which is either an emitter region or a collector region. In the MIS gate type static induction thyristor (MIS gate SI thyristor), the “first main electrode region” means a semiconductor region which is either an anode region or a cathode region. The “second main electrode region” means a semiconductor region that is either a source region or a drain region that does not become the first main electrode region in the MISFET or MISIT. In the IGBT, the “second main electrode region” means a region which is either the emitter region or the collector region which does not become the first main electrode region. In the MIS gate SI thyristor, the “second main electrode region” means a region which is either the anode region or the cathode region which does not become the first main electrode region. That is, if the “first main electrode region” is the source region, the “second main electrode region” means the drain region. If the “first main electrode region” is the emitter region, the “second main electrode region” means the collector region. If the “first main electrode region” is the anode region, the “second main electrode region” means the cathode region. Further, in the present specification, the expression, “main electrode region,” is a comprehensive expression indicating a semiconductor region of either one of the technically appropriate first main electrode region or second main electrode region.

Further, in the present specification, a case where the first conductivity type is p type and the second conductivity type is n type will be exemplarily described. However, the conductivity types may be selected in the opposite way, and the first conductivity type may be the n type and the second conductivity type may be the p type. In addition, “+” or “−” attached to “n” or “p” has a relatively high or low impurity concentration, respectively, as compared with a semiconductor region to which “+” or “−” is not attached. (In other words, it means a semiconductor region having a higher or lower specific resistance). However, in the representation of the drawings, even in the semiconductor regions denoted by the same “n” and “n”, it does not mean that the impurity concentrations (specific resistances) of the respective semiconductor regions are exactly the same. Further, regions to which “n” and “p” are attached mean semiconductor regions.

<Equivalent Circuit of Semiconductor Device>

As a semiconductor device according to an embodiment of the present invention, a high voltage integrated circuit (HVIC) will be described as an example. As shown in FIG. 1, a semiconductor device 300 according to the embodiment of the present invention is an HVIC that controls driving of a power conversion bridge circuit 500 applied to a power conversion device such as an industrial inverter.

The power conversion bridge circuit 500 includes a high potential side switching element 501 and a low potential side switching element 502 as one phase component. Each of the high potential side switching element 501 and the low potential side switching element 502 is composed of, for example, an IGBT. Each of the high-potential side switching element 501 and the low-potential side switching element 502 is not limited to the IGBT, but may be another power device such as a MOSFET. Freewheeling diodes (FWDs) 503 and 504 are connected in antiparallel to the high potential side switching element 501 and the low potential side switching element 502, respectively.

The high potential side switching element 501 and the low potential side switching element 502 are connected in series between a high potential side potential VDC supplied from a high voltage power source (not shown) and a GND potential (first potential) which is a low potential side potential. The high potential side potential VDC is, for example, about 400 V or more and about 2000 V or less. A load L such as a motor is connected to a connection point of the high potential side switching element 501 and the low potential side switching element 502, and a VS potential (second potential), which is an intermediate potential is supplied to the load L. In this embodiment, the case where the high potential side switching element 501 of the power conversion bridge circuit 500 is driven will be described as an example.

The semiconductor device 300 includes a VB terminal 31, a VS terminal 32, an input terminal 33, a VCC terminal 34, an output terminal 35, a VS terminal 36, a Psub terminal 37, and a GND terminal 38. The VB terminal 31 is connected to a terminal on the high potential side of a bootstrap capacitor 138, and the VB potential (fourth potential) is applied thereto. The VS terminal 32 is connected to a terminal on the low potential side of the bootstrap capacitor 138, and the VS potential is applied thereto. The bootstrap capacitor 138 functions as a low voltage source that is charged such that the VB potential is 15 V higher than the VS potential with reference to the VS potential.

The VB potential is the highest potential applied to the semiconductor device 300, and is kept higher than the VS potential by about 5V to 15V by the bootstrap capacitor 138 in the normal state where there is no influence from noise. The VS potential rises and falls between the high potential side potential VDC and the low potential side potential (GND potential) by the high potential side switching element 501 and the low potential side switching element 502 being complementarily turned on and off repeatedly, and fluctuates from 0 V to several hundred V and even may become a negative potential.

The input terminal 33 is connected to a microcomputer or the like (not shown), and the input signal IN which is an on/off signal is input to the input terminal 33 from the microcomputer or the like. The VCC terminal 34 is connected to the anode of a bootstrap diode 129 and is applied with the VCC potential. The VCC potential is approximately 5 V or more and 15 V or less. The output terminal 35 is connected to the gate of the high potential side switching element 501, and outputs the gate control signal OUT which is an on/off signal to the gate of the high potential side switching element 501. The VS terminal 36 is connected to a connection point between the high potential side switching element 501 and the low potential side switching element 502 of the power conversion bridge circuit 500. The Psub terminal 37 becomes the substrate potential (third potential) of the p type semiconductor substrate 101 (see FIG. 6) of the gate driver IC chip 100. The p type semiconductor substrate 101 is in an electrically floating state, and the Psub potential is a floating potential. The GND potential is applied to the GND terminal 38.

The semiconductor device 300 includes three chips of a gate driver IC chip 100, a diode and capacitance chip 210, and a high withstand voltage diode chip 220. The gate driver IC chip 100 includes a VB terminal 11, a VS terminal 12, an input terminal 13, a VCC terminal 14, an output terminal 15, a VS terminal 16, a Psub terminal 17, and a GND terminal 18. The VB terminal 11, the VS terminal 12, the input terminal 13, the VCC terminal 14, the output terminal 15, the VS terminal 16, the Psub terminal 17, and the GND terminal 18 are respectively connected to the VB terminal 31, the VS terminal 32, the input terminal 33, the VCC terminal 34, output terminal 35, VS terminal 36, Psub terminal 37, and the GND terminal 38 of the semiconductor device 300.

The gate driver IC chip 100 includes an input control circuit (control circuit) 136 on the low potential side, a level shift circuit (139, 140), and a gate drive circuit (high side gate drive circuit) 137 on the high potential side. The level shift circuits (139, 140) include a level down circuit 139 and a level up circuit 140. In FIG. 1, an n type well region (first semiconductor region) 102 and an n type well region (second semiconductor region) 103 (see FIG. 6), provided in a p type semiconductor substrate 101 of a gate driver IC chip 100 described later, are schematically indicated by the broken lines.

Although not shown, the control circuit 136 may include, for example, a complementary MOS (CMOS) circuit of an n-channel MOS transistor and a p-channel MOS transistor. The control circuit 136 includes an input terminal 51, a VCC terminal 52, a GND terminal 53, and an output terminal 54. The input terminal 51 is connected to the input terminal 13 of the gate driver IC chip 100. The VCC terminal 52 is connected to the VCC terminal 14 of the gate driver IC chip 100. The GND terminal 53 is connected to the GND terminal 18 of the gate driver IC chip 100. The output terminal 54 is connected to the level down circuit 139. The control circuit 136 operates using the GND potential applied to the GND terminal 53 as a reference potential and the VCC potential applied to the VCC terminal 52 higher than the GND potential as a power supply potential.

The level down circuit 139 includes a series circuit of a level shift resistor 126 and a level shifter 131a as a circuit for a set signal. Although not shown in FIG. 1, the level down circuit 139 further includes another circuit having the same configuration as the circuit for the set signal as the circuit for a reset signal. The level shifter 131a is composed of, for example, a p-channel MOS transistor. The gate of the level shifter 131a is connected to the output terminal 54 of the control circuit 136, and the source of the level shifter 131a is connected to the VCC terminal 52 of the control circuit 136. The connection point between the drain of the level shifter 131a and one end of the level shift resistor 126 is connected to the level up circuit 140. The other end of the level shift resistor 126 is connected to the Psub terminal 17 of the gate driver IC chip 100 and the level up circuit 140.

The level-up circuit 140 includes a series circuit of a level shift resistor 127 and a level shifter 132a as a circuit for the set signal. Although not shown in FIG. 1, the level-up circuit 140 further includes another circuit having the same configuration as the circuit for the set signal as the circuit for the reset signal. The level shifter 132a is composed of, for example, an n-channel MOS transistor. The gate of the level shifter 132a is connected to a connection point between one end of the level shift resistor 126 and the level shifter 131a of the level down circuit 139. The source of the level shifter 132a is connected to the other end of the level shift resistor 126 of the level down circuit 139 and is also connected to the Psub terminal 17 of the gate driver IC chip 100. The connection point between the drain of the level shifter 132a and one end of the level shift resistor 127 is connected to the gate drive circuit 137. The other end of the level shift resistor 127 is connected to the VB terminal 11 of the gate driver IC chip 100 and the n type well region 103, and is also connected to the gate drive circuit 137.

The gate drive circuit 137 is composed of, for example, a buffer circuit R, an n-channel MOS transistor 61, a p-channel MOS transistor 62, and the like. The gate drive circuit 137 includes a VB terminal 41, VS terminals 42 and 46, input terminals 43 and 44, and an output terminal 45. The VB terminal 41 is connected to the VB terminal 11 of the gate driver IC chip 100 and the other end of the level shift resistor 127 of the level up circuit 140. The VS terminals 42 and 46 are connected to the VS terminals 12 and 16 of the gate driver IC chip 100, respectively. The input terminal 43 is connected to a connection point between the drain of the level shifter 132a and one end of the level shift resistor 127 of the level up circuit 140. The input terminal 44 is connected to the reset signal circuit (not shown) of the level-up circuit 140. The output terminal 45 is connected to the output terminal 15 of the gate driver IC chip 100. The gate drive circuit 137 operates using the VS potential, which is supplied from the VS terminals 42 and 46, and is higher than the GND potential, as a reference potential, and a VB potential, which is supplied from the VB terminal 41 and is higher than the VS potential, as a power supply potential.

The gate driver IC chip 100 includes a first parasitic diode 141 and a second parasitic diode 142. The connection point between the anode of the first parasitic diode 141 and the anode of the second parasitic diode 142 is connected to the Psub terminal 17 of the gate driver IC chip 100. The cathode of the first parasitic diode 141 is connected to the n type well region (first semiconductor region) 102. The cathode of the second parasitic diode 142 is connected to the n type well region (second semiconductor region) 103.

The diode and capacitance chip 210 includes a diode 211 and a capacitor 212 connected in parallel between the Psub terminal 17 and the GND terminal 18 of the gate driver IC chip 100. The anode of the diode 211 and one end of the capacitor 212 are connected to the Psub terminal 17 of the gate driver IC chip 100 and the Psub terminal 37 of the semiconductor device 300. The cathode of the diode 211 and the other end of the capacitor 212 are connected to the GND terminal 18 of the gate driver IC chip 100 and the GND terminal 38 of the semiconductor device 300.

That is, the semiconductor device 300 in this embodiment of the present invention employs a substrate-GND separation scheme in which the diode 211 separates the Psub potential of the Psub terminals 17 and 37 and the GND potential of the GND terminal 18 and the GND terminal 38. The diode 211 is connected to the path of the noise current due to the −VS noise from the GND terminal 38 through the second parasitic diode 142 to the n type well region 103, in a reverse direction with respect to the direction of the noise current.

<Operation of Semiconductor Device>

Next, the operation of the semiconductor device 300 according to this embodiment of the present invention will be described with reference to FIG. 1. An input signal IN, which is an on/off signal from a microcomputer or the like, is input to the input terminal 51 of the control circuit 136. In response to the input signal IN, the control circuit 136 outputs a gate control signal having the GND potential as a reference potential to the level down circuit 139 via the output terminal 54.

The level down circuit 139 receives the gate control signal (set signal), which is output from the control circuit 136 via the output terminal 54 and which has the GND potential as a reference potential, at the gate of the level shifter 131a, and converts it to a converted gate control signal (set signal), which now has the Psub potential as a reference potential. The level down circuit 139 outputs the gate control signal (set signal) generated with reference to the Psub potential to the level up circuit 140 from a connection point between the drain of the level shifter 131a and one end of the level shift resistor 126. Similar to the set signal circuit, a reset signal circuit (not shown) of the level down circuit 139 outputs a gate control signal (reset signal) that has the Psub potential as a reference potential to the corresponding level up circuit 140.

The level-up circuit 140 receives the converted gate control signal that has the Psub potential as a reference potential and that is output from the level-down circuit 139, at the gate of the level shifter 132a and converts it to a converted gate control signal (SET) that now has he VS potential as a reference potential. The level-up circuit 140 outputs the converted gate control signal SET (set signal) that is generated with reference to the VS potential to the gate drive circuit 137 from the connection point between the drain of the level shifter 132a and one end of the level shift resistor 127. Similar to the set signal circuit, a reset signal circuit (not shown) of the corresponding level-up circuit 140 outputs a converted gate control signal (reset signal) RESET that has the VS potential as a reference potential to the gate drive circuit 137.

The gate drive circuit 137 outputs, through its output terminal 15, a gate control signal OUT, which is an ON/OFF signal, to the gate of the high potential side switching element 501 in response to the gate control signal (set signal) SET having the VS potential as a reference potential and the gate control signal (reset signal) RESET having the VS potential as a reference potential, which are output from the level-up circuit 140. The gate drive circuit 137 outputs an ON signal as the gate control signal OUT when it is receiving the set signal SET so as to turn on the gate of the high potential side switching element 501. The gate drive circuit 137 outputs an OFF signal as the gate control signal OUT when it is receiving the reset signal RESET so as to turn off the gate of the high potential side switching element 501. The high potential side switching element 501 performs a switching operation according to the gate control signal OUT from the gate drive circuit 137.

<Overall Structure of Semiconductor Device>

FIG. 2 shows a plan view of the semiconductor device 300 shown in FIG. 1 in the case the device is assembled as a Small Outline Package (SOP) 8 pin package. FIG. 3 is a cross-sectional view of the semiconductor device 300 of FIG. 2 taken along the line A-A. FIG. 4 is a cross-sectional view of the semiconductor device 300 of FIG. 2 taken along the line B-B. In FIG. 2, the sealing resin 313 shown in FIGS. 3 and 4 is omitted, and the outer edge is shown by a broken line.

As shown in FIGS. 2 to 4, the semiconductor device 300 includes three chips of a gate driver IC chip 100, a diode and capacitance chip 210, and a high withstand voltage diode chip 220. The gate driver IC chip 100, the diode and capacitance chip 210, and the high withstand voltage diode chip 220 are arranged on a lead frame 310. Around the lead frame 310, external input/output pins (leads) 314a, 314b, 314c, 314d, 314e, 314f, 314g, and 314h are arranged.

The VCC terminal 14, the input terminal 13, the GND terminal 18, the VB terminal 11, the output terminal 15, and the VS terminal (12, 16) of the gate driver IC chip 100 are electrically connected, via bonding wires 311a, 311b, 311c, 311d, 311e, and 311f, to the pins 314a, 314b, 314c, 314e, 314f, and 314h, respectively.

The GND terminal 18 of the gate driver IC chip 100 is electrically connected to the cathode electrode 150b of the diode and capacitance chip 210 via the bonding wire 311g. The VS terminals (12, 16) of the gate driver IC chip 100 are electrically connected to the cathode electrode 150c of the high withstand voltage diode chip 220 via the bonding wire 311h.

The lower surface electrode of the gate driver IC chip 100, the lower surface electrode (anode electrode) of the diode and capacitance chip 210, and the lower surface electrode (anode electrode) of the high withstand voltage diode chip 220 are electrically connected to each other via the lead frame 310, and are also connected to a pin 314d that is continuous with the lead frame 310.

<Structure of Gate Driver IC Chip>

As shown on the left side of FIG. 5, the gate driver IC chip 100 shown in FIGS. 2 to 4 includes a control circuit 136, a level down circuit 139, and a high withstand voltage junction termination structure (HVJT) 130a, which are formed on one side (i.e., here, left side) of the p type semiconductor substrate 101.

The control circuit 136 is provided in a low potential side circuit region (low side circuit region) 133 provided on the upper surface side of the p type semiconductor substrate 101. The high withstand voltage junction termination structure 130a is provided so as to surround the low-side circuit region 133. The isolation withstand voltage between the p type semiconductor substrate 101 of the high withstand voltage junction termination structure 130a and the low-side circuit region 133 is set to about 200V, for example. With the high withstand voltage junction termination structure 130a, even when the Psub potential of the p type semiconductor substrate 101 becomes about − 200V, the withstand voltage between the low-side circuit region 133 and the p type semiconductor substrate 101 can be maintained and a breakdown of the low-side circuit region 133 can be prevented.

The level down circuit 139 includes a level shifter 131a for a set signal and a level shifter 131b for a reset signal. The level shifters 131a and 131b are each configured by a p-channel MOS transistor integrally formed with the high withstand voltage junction termination structure 130a.

As shown on the right side of FIG. 5, the gate driver IC chip 100 further includes a gate drive circuit 137, a level-up circuit 140, and a high withstand voltage junction termination structure 130, which are provided on the other side (i.e., right side) of the p type semiconductor substrate 101.

The gate drive circuit 137 is provided in a high potential side circuit region (high side circuit region) 135 provided on the upper surface side of the p type semiconductor substrate 101. The high withstand voltage junction termination structure 130 is provided so as to surround the high side circuit region 135. The withstand voltage of the high withstand voltage junction termination structure 130 is set to 1200 V, for example. With the high withstand voltage junction termination structure 130, it is possible to apply a voltage that is higher than the potential of the low side circuit region 133 by about 1200V to the high side circuit region 135.

The level-up circuit 140 includes a level shifter 132a for a set signal and a level shifter 132b for a reset signal. The level shifters 132a and 132b are each composed of, for example, an n-channel MOS transistor integrally formed with the high withstand voltage junction termination structure 130.

FIG. 6 shows a cross-sectional view of the gate driver IC chip 100 shown in FIG. 5 viewed from the A-A direction. The gate driver IC chip 100 includes a p type semiconductor substrate 101 made of silicon (Si). The specific resistance of the p type semiconductor substrate 101 is, for example, about 300 Ωcm to 500 Ωcm. The potential of the p type semiconductor substrate 101 (substrate potential) is the Psub potential, which is a floating potential separated from the GND potential by the diode 211.

In the present specification, the “semiconductor substrate” is not limited to a base member (bulk substrate) obtained by cutting an ingot grown by the Czochralski method (CZ method), the floating zone method (FZ method) or the like into a wafer shape. The expression, “semiconductor substrate,” comprehensively includes, in addition to a bulk substrate as a base member, a laminated structure in which various processes are performed on the base substrate, such as an epitaxial growth substrate on which a layer is epitaxially grown on the base substrate and an SOI substrate in which an insulating film is in contact with the back surface of the base member. That is, the “semiconductor substrate” is a generic term indicating a superordinate concept that can include not only a base substrate, but also various laminated structures and an active region corresponding to only a part of a laminated structure, for example.

As shown on the left side of FIG. 6, an n type well region 102 is provided on the upper surface side of the p type semiconductor substrate 101. The impurity concentration of then type well region 102 is, for example, about 4×10¹⁶ cm⁻³, and the diffusion depth of the n type well region 102 is, for example, about 12 μm. The n type well region 102 constitutes the low side circuit region 133 shown in FIG. 5. A first parasitic diode 141 is formed at the junction 102a between the n type well region 102 and the p type semiconductor substrate 101.

A control circuit 136 is provided on the upper surface side of the n type well region 102. The control circuit 136 includes a p type diffusion region (third semiconductor region) 111 provided on the upper surface side of the n type well region 102 and a p+ type contact region 109 having an impurity concentration higher than the p type diffusion region 111 on the upper surface side of the p type diffusion region 111. The GND potential, which is the reference potential of the control circuit 136, is applied to the p+ type contact region 109.

A high withstand voltage junction termination structure 130a is provided on the upper surface side of the p type semiconductor substrate 101 so as to surround the n type well region 102. The width of the high withstand voltage junction termination structure 130a is, for example, about 200 μm. The high withstand voltage junction termination structure 130a includes an n− type diffusion region 104 provided on the upper surface side of the p type semiconductor substrate 101, and p− type diffusion regions 117 and p− drift region 118, provided on the upper surface side of the n− type diffusion region 104. The p type semiconductor substrate 101, the n− type diffusion region 104, the p− type diffusion region 117, and the p− type drift region 118 together form a double RESURF structure.

The impurity concentration of the n− type diffusion region 104 is, for example, about 7×10¹⁵ cm⁻³, and the diffusion depth of the n− type diffusion region 104 is, for example, about 10 μm. The impurity concentration of each of the p− type diffusion region 117 and the p− type drift region 118 is, for example, about 6×10¹⁵ cm⁻³, and the diffusion depth of each of the p− type diffusion region 117 and the p− type drift region 118 is, for example, about 2 μm.

The level shifter 131a is, for example, a p-channel MOS transistor integrally formed with the high withstand voltage junction termination structure 130a. The level shifter 131a includes a p− type drift region 118 provided straddling the n− type diffusion region 104 and the n type well region 102, a p+ type drain region (first main electrode region) 113 provided on the upper surface side of the p− type drift region 118, and a p+ type source region (second main electrode region) 121 provided on the upper surface side of the n type well region 102.

The level shifter 131a further includes an n+ type back gate region 107 having a higher impurity concentration than the n type well region 102, provided on the upper surface side of the n type well region 102 so as to be in contact with the p+ type source region 121. The VCC potential is applied to the n+ type back gate region 107.

The level shifter 131a further includes a gate electrode 123 provided from the upper surface of the p+ type source region 121 to the upper surface of the p+ type drain region 113 with a gate insulating film 125 interposed therebetween. The gate insulating film 125 can be formed of an insulating film such as a silicon oxide film (SiO₂ film), a silicon nitride film (Si₃N₄ film) other than the SiO₂ film, or a laminated film of insulating films including a SiO₂ film, a Si₃N₄ film, etc. The gate electrode 123 is formed of, for example, a polycrystalline silicon (doped polysilicon) film into which impurities are introduced, a refractory metal, a refractory metal silicide, or the like.

As shown on the right side of FIG. 6, an n type well region 103 is provided on the upper surface side of the p type semiconductor substrate 101 so as to be separated from the n type well region 102. The n type well region 103 constitutes the high side circuit region 135 shown in FIG. 5. The impurity concentration of the n type well region 103 may be equal to that of the n type well region 102, and the diffusion depth of the n type well region 103 may be equal to that of the n type well region 102. A second parasitic diode 142 is formed at the junction 103a between the n type well region 103 and the p type semiconductor substrate 101.

A gate drive circuit 137 is provided on the upper surface side of the n type well region 103. The gate drive circuit 137 includes a p type diffusion region (fourth semiconductor region) 112 provided on the upper surface side of the n type well region 103 and a p+ type contact region 110 having a high impurity concentration than the p type diffusion region 112, provided on the upper surface side of the p type diffusion region 112. The VS potential, which is the reference potential of the gate drive circuit 137, is applied to the p+ type contact region 110.

An n+ type contact region 108 having a higher impurity concentration than the n type well region 103 is provided on the upper surface side of the n type well region 103. The VB potential, which is a power supply potential of the gate drive circuit 137, is applied to the n+ type contact region 108.

A high withstand voltage junction termination structure 130 is provided on the upper surface side of the p type semiconductor substrate 101 so as to surround the n type well region 103. The width of the high withstand voltage junction termination structure 130 is, for example, about 200 μm. The high withstand voltage junction termination structure 130 is provided on the upper surface side of the p type semiconductor substrate 101 so as to surround the n type well region 103, and has an n− type diffusion region 105 having a lower impurity concentration than the n type well region 103, and p− type diffusion region 120 provided on the upper surface side of the n− type diffusion region 105. The n− type diffusion region 105, the p− type diffusion region 120, and the p type semiconductor substrate 101 form a double RESURF structure.

The impurity concentration of the n− type diffusion region 105 is, for example, about 7×10¹⁵ cm⁻³, and the diffusion depth is, for example, about 10 μm. The impurity concentration of the p− type diffusion region 120 is, for example, about 6×10¹⁵ cm⁻³, and the diffusion depth of the p− type diffusion region 120 is, for example, about 2 μm.

The level shifter 132a is composed of an n-channel MOS transistor integrally formed with the high withstand voltage junction termination structure 130. The level shifter 132a further includes an n− type drift region 106 provided on the upper surface side of the p type semiconductor substrate 101, and a p− type diffusion region 119 provided on the upper surface side of the n− type drift region 106. A p− type isolation region 147 is provided between the n− type drift region 106 and the n− type diffusion region 105.

The impurity concentration of the n− type drift region 106 is, for example, about 7×10¹⁵ cm⁻³, and the diffusion depth of the n− type drift region 106 is, for example, about 10 μm. The impurity concentration of the p− type diffusion region 119 is, for example, about 6×10¹⁵ cm⁻³, and the diffusion depth of the p− type diffusion region 119 is, for example, about 2 μm. The impurity concentration of the p− type isolation region 147 is, for example, about 4×10¹⁵ cm⁻³, and the diffusion depth of the p− type isolation region 147 is, for example, about 10 μm.

The level shifter 132a includes an n+ type drain region (first main electrode region) 116 having an impurity concentration higher than that of the n− type drift region 106, provided on the upper surface side of the n− type drift region 106 in contact with the p− type diffusion region 119. The level shifter 132 a further includes a p type channel formation region 122 provided on the upper surface side of the n− type drift region 106 and an n+ type source region (second main electrode region) 115 provided on the upper surface side of the p type channel formation region 122. The level shifter 132a also includes a gate electrode 124 provided from the upper surface of the n+ type source region 115 to the upper surface of the p− type diffusion region 119 with a gate insulating film 125 interposed therebetween.

A lower surface electrode 402a is provided on the lower surface side of the p type semiconductor substrate 101. The lower surface electrode 402a is electrically connected to the anode of the diode 211 and one end of the capacitor 212, included in the diode and capacitance chip 210, and is also electrically connected to the anode of the diode 221 included in the high withstand voltage diode chip 220.

<Diode and Capacitance Chip Configuration>

FIG. 7A shows a plan view of the diode and capacitance chip 210 shown in FIG. 2, and FIG. 7B shows a cross-sectional view taken along the line A-A of FIG. 7A. As shown in FIGS. 7A and 7B, the diode and capacitance chip 210 has, for example, a rectangular parallelepiped shape.

As shown in FIG. 7B, the diode and capacitance chip 210 is a chip in which a vertical diode (high withstand voltage diode) 211 having a withstand voltage of about 200 V and a capacitor 212 are integrated. The diode and capacitance chip 210 includes a p type semiconductor substrate 101b. The specific resistance of the p type semiconductor substrate 101b is, for example, about 30 Ωcm to 50 Ωcm.

An n type cathode region (main electrode region) 144b is provided on the upper surface side of the p type semiconductor substrate 101b. The impurity concentration of the n type cathode region 144b is, for example, about 4×10¹⁶ cm⁻³, and the diffusion depth of the n type cathode region 144b is, for example, about 12 μm. The diode 211 is formed by the n type cathode region 144b and the p type semiconductor substrate 101b.

An n+ type contact region 148b having an impurity concentration higher than that of the n type cathode region 144b is provided on the upper surface side of the n type cathode region 144b. A cathode electrode 150b is provided above the n+ type contact region 148b via interlayer insulating films (insulating films) 155a, 155b, and 155c. The cathode electrode 150b is electrically connected to the n+ type contact region 148b via a contact 158 penetrating the interlayer insulating films 155a, 155b, and 155c. A lower surface electrode (anode electrode) 402b is provided on the lower surface of the p type semiconductor substrate 101b.

As an edge structure of the diode and capacitance chip 210, an n− type diffusion region 145b having a lower impurity concentration than the n type cathode region 144b is formed on the upper surface side of the p type semiconductor substrate 101b so as to surround the n type cathode region 144b. The impurity concentration of the n− type diffusion region 145b is, for example, about 7×10¹⁵ cm⁻³, and the diffusion depth of the n− type diffusion region 145b is, for example, about 10 μm.

A p− type diffusion region 146b is provided on the upper surface side of the n− type diffusion region 145b. The impurity concentration of the p− type diffusion region 146b is, for example, about 6×10¹⁵ cm⁻³, and the diffusion depth of the p− type diffusion region 146b is, for example, about 2 μm. A p type diffusion region 143b having an impurity concentration higher than that of the p− type diffusion region 146b is provided on the upper surface side of the p type semiconductor substrate 101b so as to be in contact with the n− type diffusion region 145b and the p− type diffusion region 146b. The p type semiconductor substrate 101b, the n− type diffusion region 145b, the p− type diffusion region 146b, and the p type diffusion region 143b form a double RESURF structure so as to secure a sufficient lateral withstand voltage.

An interlayer insulating film 155a, a conductive film (lower layer conductive film) 153, an interlayer insulating film 155b, a conductive film (upper layer conductive film) 154, and an interlayer insulating film 155c are sequentially formed on the upper surface of the p type semiconductor substrate 101b. The lower conductive film 153, the upper conductive film 154, and the interlayer insulating film 155b form the capacitor 212. The capacitance of the capacitor 212 is, for example, about 1000 pF.

The lower-layer side conductive film 153 and the upper-layer side conductive film 154 are made of, for example, doped polysilicon. They may be made of a conductive material such as metal other than doped polysilicon. The lower conductive film 153 is electrically connected to the cathode electrode 150b via contacts 156 and 159 that penetrate the interlayer insulating films 155a, 155b, and 155c. The lower conductive film 153 has, for example, an annular (frame-shaped) planar pattern so as to surround the periphery of the contact 158.

The upper conductive film 154 is electrically connected to the anode electrode 402b via contacts 160 and 161 penetrating the interlayer insulating film 155c, a metal wiring 152 arranged on the interlayer insulating film 155c, and contacts 151 and 157 penetrating the interlayer insulating films 155a, 155b, and 155c, the p type diffusion region 143b, and the p type semiconductor substrate 101b. That is, the capacitor 212 and the diode 211 are connected in parallel between the cathode electrode 150b and the anode electrode 402b.

As shown in FIG. 7A, the cathode electrode 150b has, for example, a substantially elliptical planar pattern. The planar pattern shape of the cathode electrode 150b is not limited thereto, and may be circular or rectangular, for example. The metal wiring 152 has an annular (frame-shaped) planar pattern so as to surround the cathode electrode 150b, for example. As shown by the broken line in FIG. 7A, the upper conductive film 154 has, for example, an annular (frame-shaped) planar pattern. Although not shown in FIG. 7A, the lower conductive film 153 shown in FIG. 7B has an annular (frame-shaped) planar pattern so as to overlap the planar pattern of the upper conductive film 154, for example.

<Structure of High Withstand Voltage Diode Chip>

FIG. 8 shows a cross-sectional view of the main parts of the high withstand voltage diode chip 220 shown in FIG. 2. The basic structure of the high withstand voltage diode chip 220 is similar to that of the diode 211 of the diode and capacitance chip 210, but the impurity concentration of each diffusion layer is appropriately set so as to realize a withstand voltage of 1200V.

The high withstand voltage diode chip 220 includes a p type semiconductor substrate 101c. The specific resistance of the p type semiconductor substrate 101c is, for example, about 300 Ωcm to 500 Ωcm. An n type cathode region (main electrode region) 144c is provided on the upper surface side of the p type semiconductor substrate 101c. The impurity concentration of the n type cathode region 144c is, for example, about 4×10¹⁶ cm⁻³, and the diffusion depth of the n type cathode region 144c is, for example, about 12 μm. A diode 221 is formed by the n type cathode region 144c and the p type semiconductor substrate 101c.

An n+ type contact region 148c having a higher impurity concentration than that of the n type cathode region 144c is provided on the upper surface side of the n type cathode region 144c. A cathode electrode 150c is provided on the upper surface of the n+ type contact region 148c. A lower surface electrode (anode electrode) 402c is provided on the lower surface of the p type semiconductor substrate 101c.

As an edge structure of the high withstand voltage diode chip 220, an n− type diffusion region 145c having a lower impurity concentration than the n type cathode region 144c is provided on the upper surface side of the p type semiconductor substrate 101c so as to surround the periphery of the n type cathode region 144c. The impurity concentration of the n− type diffusion region 145c is, for example, about 7×10¹⁵ cm⁻³, and the diffusion depth of the n− type diffusion region 145c is, for example, about 10 μm.

A p− type diffusion region 146c is provided on the upper surface side of the n− type diffusion region 145c. The impurity concentration of the p− type diffusion region 146c is, for example, about 6×10¹⁵ cm⁻³, and the diffusion depth of the p− type diffusion region 146c is, for example, about 2 μm. A p type diffusion region 143c having a higher impurity concentration than the p− type diffusion region 146c is provided on the upper surface side of the p type semiconductor substrate 101c so as to be in contact with the n− type diffusion region 145c and the p− type diffusion region 146c. The p type semiconductor substrate 101c, the n− type diffusion region 145c, the p− type diffusion region 146c, and the p type diffusion region 143c form a double RESURF structure so as to secure a sufficient lateral withstand voltage.

### First Comparison Example

Next, as a semiconductor device according to a first comparison example, an HVIC using a self-separation process will be described. FIG. 9 shows a plan view of a semiconductor device 200 according to the first comparison example, and FIG. 10 shows a cross-sectional view of main parts seen from the direction A-A of FIG. 9.

As shown in FIGS. 9 and 10, the semiconductor device 200 of the first comparison example is constructed of only one chip that corresponds to the gate driver IC chip 100 of the embodiment of the present invention shown in FIGS. 5 and 6, and in that regard, differs from the semiconductor device 300 of the embodiment of the present invention, which includes three chips, as shown in FIG. 2. Further, the semiconductor device 200 of the first comparison example differs from the gate driver IC chip 100 of the embodiment shown in FIGS. 5 and 6 in that there is no level down circuit between the control circuit 136 and the level up circuit 140, and that there is no high withstand voltage junction termination structure around the low side circuit region 133.

Further, the semiconductor device 200 of the first comparison example differs from the gate driver IC chip 100 of to the embodiment shown in FIGS. 5 and 6 in that, as shown in FIG. 10, the p+ type contact region 141 is provided on the upper surface side of the p type semiconductor substrate 101. The GND potential is applied to the p+ type contact region 141, and the Psub potential of the p type semiconductor substrate 101 becomes the GND potential.

FIG. 11 shows an equivalent circuit diagram of the semiconductor device 200 of the first comparison example shown in FIGS. 9 and 10. The semiconductor device 200 of the first comparison example differs from the semiconductor device 300 of the embodiment of the present invention shown in FIG. 1 in that the GND potential is applied to the Psub terminal 28. The source of the level shifter 132a of the level-up circuit 140 is connected to the Psub terminal 28, and the anode of the first parasitic diode 141 and the anode of the second parasitic diode 142 are also connected to the Psub terminal 28.

### Second Comparison Example

Next, as a semiconductor device according to a second comparison example, a substrate/GND separation type HVIC will be described. The semiconductor device 600 according to the second comparison example shown in FIG. 12 differs from the semiconductor device 300 of the embodiment of the present invention shown in FIG. 1 in that the diode chip 210a is composed of only the diode 211 and does not have a capacitor attached to the diode 211. The other configuration of the semiconductor device 600 of the second comparison example is the same as that of the semiconductor device 300 of the embodiment of the present invention shown in FIG. 1. In terms of circuit configuration (apart from the chip arrangement, such as having separate chips 210 and 220), the circuitry of FIG. 12 is the same as that shown in FIG. 18 of Patent Document 4 mentioned above.

<Behavior when the −VS Noise Occurs>

Next, with respect to each of the semiconductor device 300 of the embodiment of the present invention shown in FIG. 1, the semiconductor device 200 of the first comparison example shown in FIG. 11, and the semiconductor device 600 of the second comparison example shown in FIG. 12, the behavior of the device when the −VS noise occurs will be described.

In each of the semiconductor device 300 of the embodiment of the present invention shown in FIG. 1, the semiconductor device 200 of the first comparison example shown in FIG. 11, and the semiconductor device 600 of the second comparison example shown in FIG. 12, when the load L connected to the high-potential side switching element 501 is inductive, the VS potential impulsively drops below the GND potential due to the counter electromotive force generated in the load at the moment when the high-potential side switching element 501 is turned off, thereby generating the −VS noise. When the voltage (absolute value) of the −VS noise is larger than the voltage between the VB terminal 31 and the VS terminal 32, not only the VS potential, but also the VB potential becomes lower than the GND potential. For example, when the −VS noise is −200V and the voltage between the VB terminal 31 and the VS terminal 32 is 15V, the VB potential decreases to a level that is 185V (15V-200V) lower than the GND potential.

In the semiconductor device 200 of the first comparison example shown in FIG. 11, when the VB potential becomes lower than the GND potential due to the −VS noise, the second parasitic diode 142 between the VB terminal 21 and the Psub terminal 28 having the GND potential is forward biased. When the forward voltage of the second parasitic diode 142 becomes 0.6 V or more, the second parasitic diode 142 becomes conductive. Due to the conduction of the second parasitic diode 142, noise current flows through the second parasitic diode 142 from the Psub terminal 28 at the GND potential into the n type well region 103 connected to the VB terminal 21, as shown by the arrow in FIG. 11. This causes malfunction of the gate drive circuit 137. The withstand voltage of the semiconductor device 200 of the first comparison example against the −VS noise is only about − 50 V when the noise duration is 500 ns, for example.

In contrast, in the semiconductor device 300 of the embodiment of the present invention shown in FIG. 1 and the semiconductor device 600 of the second comparison example shown in FIG. 12, when the VB potential becomes lower than the GND potential due to the −VS noise, the high withstand voltage diode 221 becomes forward biased and is turned on. On the other hand, the diode 211 is turned off by the reverse bias. Due to the diode 211, the impedance between the p type semiconductor substrate 101 and GND becomes higher than the impedance of the parasitic diode 142 by 10 times or more. For this reason, the Psub potential follows the VS potential and decreases to nearly −200V, and the difference between the Psub potential and the VS potential becomes about 0.6V, which is the forward voltage of the high withstand voltage diode 221.

Further, since the VB potential is higher than the VS potential by about 15V and the VB potential is higher than the Psub potential, the second parasitic diode 142 is not turned on. As a result, a noise current that would flow from the GND terminal 18 into the n type well region 103 through the noise current path passing through the second parasitic diode 142 can be prevented. Thus, malfunction of the gate drive circuit 137 arranged in the n type well region 103 can be prevented.

Further, since the low-side circuit region 133 is surrounded by the high withstand voltage junction termination structure 130a having a withstand voltage of about 200V, even if the Psub potential is lowered by about 200V from the GND potential, voltage isolation between the low-side circuit region 133 and the p type semiconductor substrate 101 is maintained, and the control circuit 136 can operate normally with reference to GND. Therefore, the gate drive circuit 137 can operate normally without malfunctioning.

As explained above, in the semiconductor device 300 of the embodiment of the present invention shown in FIG. 1 and the semiconductor device 600 of the second comparison example shown in FIG. 12, as compared with the semiconductor device 200 of the first comparison example, it is possible to prevent malfunction of the circuit due to the −VS noise, thereby improving resistance against the −VS noise.

<Behavior when the dV/Dt Noise Occurs>

Next, the behavior of the semiconductor device 300 of the embodiment of the present invention shown in FIG. 1 and the semiconductor device 600 of the second comparison example shown in FIG. 12 when the dV/dt noise occurs will be described.

In each of the semiconductor device 300 of the embodiment of the present invention shown in FIG. 1 and the semiconductor device 600 of the second comparison example shown in FIG. 12, the fluctuation of the VS potential during the switching operation of the high potential side switching element 501 causes the dV/dt noise.

In each of the semiconductor device 300 of the embodiment of the present invention and the semiconductor device 600 of the second comparison example, when the dV/dt noise occurs, and when the Psub potential rises above the GND potential and the forward voltage of the diode 211 exceeds 0.6V, the diode 211 is turned on, suppressing the rise of the Psub potential.

However, in the semiconductor device 600 of the second comparison example, when the ON resistance of the diode 211 is large, the Psub potential may increase and exceed the VCC potential. When the Psub potential exceeds the VCC potential, the first parasitic diode 141 is turned on, causing a parasitic bipolar operation. As a result, an abnormal current may flow into the control circuit 136, causing malfunction of the control circuit 136 and the like.

On the other hand, in the semiconductor device 300 of the embodiment of the invention shown in FIG. 1, the capacitor 212 connected in parallel to the diode 211 functions as a bootstrap capacitor that supplies a negative voltage to the Psub terminal 17, suppressing the parasitic bipolar operation due to the rise of the Psub potential. Therefore, compared with the semiconductor device 600 of the second comparison example, it is possible to suppress an increase in the Psub potential when the dV/dt noise occurs, and it is possible to prevent malfunction of the control circuit 136 and the like.

Referring to FIGS. 13A and 13B, the respective behaviors of the semiconductor device 300 of the embodiment of the present invention and the semiconductor device 600 of the second comparison example when the −VS noise and the dV/dt noise occur are compared. FIG. 13A shows a change in the VS potential when the −VS noise and the dV/dt noise occur, and FIG. 13B shows a change in Psub potential with respect to the change in the VS potential shown in FIG. 13A. The change in the VS potential shown in FIG. 13A is common to the semiconductor device 300 of the embodiment of the present invention and the semiconductor device 600 of the second comparison example. In FIG. 13B, a change in the Psub potential of the semiconductor device 300 of the embodiment of the present invention is labelled as “Embodiment,” and is indicated by a solid line, and a change in the Psub potential of the semiconductor device 600 of the second comparison example is labelled as “Comparison Example,” and is indicated by a broken line.

When the −VS noise is generated as shown in the area A1 of FIG. 13A, in both cases of the semiconductor device 300 of the embodiment of the present invention and the semiconductor device 600 of the second comparison example, the Psub potential follows the VS potential and decreases by the amount ΔV0, as shown in FIG. 13B.

Next, as shown in FIG. 13A, when the −VS noise period ends and the VS potential rises to 0 V, the Psub potential starts rising later than the VS potential, as shown in FIG. 13B. The rise of the Psub potential is caused by the leakage current of the diode 211 connected between the Psub terminal 17 and the GND terminal 38, charging the capacitance between the Psub terminal 17 and the GND terminal 38.

In the semiconductor device 600 of the second comparison example, the capacitance between the Psub terminal 17 and the GND terminal 38 is mainly a parasitic capacitance of the diode 211. On the other hand, in the semiconductor device 300 of the embodiment of the present invention, since the capacitor 212 is connected in parallel to the diode 211, the capacitor 212 constitutes the capacitance between the Psub terminal 17 and the GND terminal 38 together with the parasitic capacitance of the diode 211. Therefore, the capacitance between the Psub terminal 17 and the GND terminal 38 is larger than that of the semiconductor device 600 of the second comparison example. Therefore, the increase in the Psub potential after the end of the −VS noise period becomes slower in the semiconductor device 300 of the embodiment of the present invention than in the semiconductor device 600 of the second comparison example.

Next, as shown in a region A2 of FIG. 13, when the dV/dt noise occurs, a displacement current flows between the VS terminal and Psub. This current charges the capacitance between the Psub terminal 17 and the GND terminal 38, and thus raises the Psub potential. At this time, similarly to the rise of the Psub potential after the end of the −VS noise period, due to the effect of the capacitor 212, the potential change amount ΔV1 of the semiconductor device 300 of the embodiment of the present invention is suppressed more than the change amount ΔV2 of the semiconductor device 600 of the second comparison example.

As described above, according to the semiconductor device 300 of the embodiment of the present invention, the diode 211 separates the GND potential and the Psub potential from each other as compared with the semiconductor device 200 of the first comparison example. As a result, malfunction of the circuit can be prevented. Furthermore, because the semiconductor device 300 of the embodiment of the present invention has the capacitor 212 connected in parallel to the diode 211, as compared with the semiconductor device 600 of the second comparison example, when the dV/dt noise occurs, it is possible to suppress an increase in the Psub potential more, reliably preventing malfunction of the circuit.

<First Modification>

A semiconductor device 300a according to a first modified example of the embodiment of the present invention is different from the semiconductor device 300 of the embodiment of the present invention shown in FIG. 1 in that the high withstand voltage diode chip 220 is not provided, as shown in FIG. 14.

According to the semiconductor device 300a of the first modified example of the embodiment of the present invention, due to the absence of the high withstand voltage diode chip 220, the parasitic diode 142 turns on when −VS noise is generated. However, since the Psub terminal 17 and the GND terminal 18 are separated by the diode 211, the noise current flowing through the parasitic diode 142 when the −VS noise is generated is suppressed as compared with the semiconductor device 200 of the first comparative example. As a result, it is possible to prevent circuit malfunction due to the −VS noise as compared with the semiconductor device 200 of the first comparative example. Further, similarly to the semiconductor device 300 of the embodiment of the present invention, since the capacitor 212 functions as a bootstrap capacitor that supplies a negative voltage to the Psub terminal 17, the parasitic bipolar operation due to the increase in the Psub potential when the dV/dt noise is generated is suppressed. As a result, it is possible to prevent malfunction of the circuit due to dV/dt noise as compared with the semiconductor device 600 of the second comparative example.

<Second Modification>

A semiconductor device 300b according to a second modified example of the embodiment of the present invention differs from semiconductor device 300 of the embodiment of the present invention shown in FIG. 1 in that one end of the capacitor 212 is connected to the VCC terminal 34, as shown in FIG. 15.

According to the semiconductor device 300b of the second modified example of the embodiment of the present invention, although one end of the capacitor 212 is connected to the VCC terminal 34, because the capacitor 212 functions as a bootstrap capacitor that supplies a negative voltage to the Psub terminal 17, as in the semiconductor device 300 of the embodiment of the present invention, it is possible to prevent malfunction of the circuit due to the −VS noise and the dV/dt noise.

<Third Modification>

A semiconductor device 300c according to a third modified example of the embodiment of the present invention differs from the semiconductor device 300 of the embodiment shown in FIG. 1 in that the level down circuit 139 is not provided, as shown in FIG. 16.

The semiconductor device 300c of the third modified example of the embodiment of the present invention includes a gate resistor 201, a gate protection diode 202, and a protection diode 203. One end of the gate resistor 201 is connected to the output terminal 54 of the control circuit 136. The other end of the gate resistor 201 is connected to the gate of the level shifter 132a of the level up circuit 140. The gate resistor 201 prevents a large current from flowing between the output terminal 54 of the control circuit 136 and the gate of the level shifter 132a due to a negative voltage surge.

The anode of the gate protection diode 202 is connected to the source of the level shifter 132a. The cathode of the gate protection diode 202 is connected to the gate of the level shifter 132a. The anode of the protection diode 203 is connected to the GND terminal 18. The cathode of the protection diode 203 is connected to one end of the gate resistor 201 and the output terminal 54 of the control circuit 136. The protection diode 203 prevents a large negative voltage from being applied to the output terminal 54 of the control circuit 136.

According to the semiconductor device 300b of the third modified example of the embodiment of the present invention, as in the semiconductor device 300 of the embodiment of the present invention, it is possible to prevent malfunction of the circuit due to the −VS noise and the V/dt noise.

### Other Embodiments

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

For example, in the embodiments of the present invention, the case where the Si substrate is used as the semiconductor substrate 101, 101b, and 101c of the respective chips of the semiconductor device 300 is illustrated, but a compound semiconductor substrate such as gallium arsenide (GaAs) may be used. Further, a substrate made of wide band gap semiconductor, such as silicon carbide (SiC), gallium nitride (GaN) or diamond, may be used. Further, a narrow gap semiconductor substrate such as indium antimonide (InSb) or a semi-metal substrate may be used.

Further, in the embodiments of the present invention, the case where the level down circuit 139 and the level up circuit 140 of the level shift circuit (139, 140) respectively include two circuits of a set signal circuit and a reset signal circuit is illustrated. However, the level down circuit 139 and the level up circuit 140 may include only one circuit that outputs an on/off signal.

Further, in the embodiments of the present invention, the case where the diode and capacitance chip 210 in which the diode 211 and the capacitor 212 are integrated is provided separately from the gate driver IC chip 100 has been illustrated, but the diode 211 and the capacitor 212 may be built in the gate driver IC chip 100. Further, only the diode 211 of the diode 211 and the capacitor 212 may be built in the gate driver IC chip 100, and the capacitor 212 may be configured as a separate chip. Further, only the capacitor 212 of the diode 211 and the capacitor 212 may be built in the gate driver IC chip 100, and the diode 211 may be configured as a separate chip. Further, the diode 211 and the capacitor 212 may be separate chips.

Further, although the HVIC is illustrated as the semiconductor device in the embodiments of the present invention, the present invention is not limited to the HVIC, and the present invention can be applied to various other semiconductor devices.

What is claimed is:

1. A semiconductor device, comprising:
a first semiconductor substrate of a first conductivity type;
a first semiconductor region of a second conductive type, provided in the first semiconductor substrate, forming a first parasitic diode with the first semiconductor substrate;
a second semiconductor region of the second conductive type, provided in the first semiconductor substrate so as to be separated from the first semiconductor region, forming a second parasitic diode with the first semiconductor substrate;
a control circuit that is provided in the first semiconductor region and outputs a gate control signal;
a gate drive circuit provided in the second semiconductor region;
a level shift circuit that converts the gate control signal from the control circuit to a converted gate control signal, and outputs the converted gate control signal to the gate drive circuit;
a diode connected to a path of a noise current caused by a negative voltage noise passing through the second parasitic diode, the diode being connected to the path in a direction opposite to a direction in which the noise current would flow; and
a capacitor connected to an anode of said diode.

2. A semiconductor device, comprising:
a first semiconductor substrate of a first conductivity type;
a first semiconductor region of a second conductive type, provided in the first semiconductor substrate;
a second semiconductor region of the second conductive type, provided in the first semiconductor substrate so as to be separated from the first semiconductor region;
a third semiconductor region of the first conductivity type provided in the first semiconductor region;
a fourth semiconductor region of the first conductivity type provided in the second semiconductor region;
a control circuit that is provided in the first semiconductor region and outputs a first gate control signal having a potential of the third semiconductor region as a reference potential;
a gate drive circuit that is provided in the second semiconductor region and operates using a potential of the fourth semiconductor region as a reference potential;
a level shift circuit that converts the first gate control signal that has the potential of the third semiconductor region as the reference potential output from the control circuit to a second gate control signal that has the potential of the fourth semiconductor region as a reference potential, and outputs the second gate control signal to the gate drive circuit;
a diode, a cathode of which is connected to the third semiconductor region and an anode of which is connected to the first semiconductor substrate; and
a capacitor connected in parallel with the diode.

3. The semiconductor device according to claim 2, wherein the level shift circuit includes:
a level down circuit for converting the first gate control signal output from the control circuit into a third gate control signal having a potential of the first semiconductor substrate as a reference potential; and
a level-up circuit for converting the third gate control signal into the second gate control signal.

4. The semiconductor device according to claim 1, wherein the diode and the capacitor are integrated in a second semiconductor substrate that is different from the first semiconductor substrate.

5. The semiconductor device according to claim 4, wherein the diode is formed by the second semiconductor substrate and a main electrode region of the second conductivity type, provided in the second semiconductor substrate.

6. The semiconductor device according to claim 4, wherein the capacitor includes a first conductive film formed on the second semiconductor substrate and a second conductive film provided on the first conductive film so as to sandwich an insulating film with the first conductive film.

7. The semiconductor device according to claim 5, wherein the capacitor includes a first conductive film formed on the second semiconductor substrate and a second conductive film provided on the first conductive film so as to sandwich an insulating film with the first conductive film.

8. The semiconductor device according to claim 2, wherein the diode and the capacitor are integrated in a second semiconductor substrate that is different from the first semiconductor substrate.

9. The semiconductor device according to claim 8, wherein the diode is formed by the second semiconductor substrate and a main electrode region of the second conductivity type, provided in the second semiconductor substrate.

10. The semiconductor device according to claim 8, wherein the capacitor includes a first conductive film formed on the second semiconductor substrate and a second conductive film provided on the first conductive film so as to sandwich an insulating film with the first conductive film.

11. The semiconductor device according to claim 9, wherein the capacitor includes a first conductive film formed on the second semiconductor substrate and a second conductive film provided on the first conductive film so as to sandwich an insulating film with the first conductive film.

12. The semiconductor device according to claim 3, wherein the diode and the capacitor are integrated in a second semiconductor substrate that is different from the first semiconductor substrate.

13. The semiconductor device according to claim 12, wherein the diode is formed by the second semiconductor substrate and a main electrode region of the second conductivity type, provided in the second semiconductor substrate.

14. The semiconductor device according to claim 12, wherein the capacitor includes a first conductive film formed on the second semiconductor substrate and a second conductive film provided on the first conductive film so as to sandwich an insulating film with the first conductive film.

15. The semiconductor device according to claim 13, wherein the capacitor includes a first conductive film formed on the second semiconductor substrate and a second conductive film provided on the first conductive film so as to sandwich an insulating film with the first conductive film.
